(19) United States
(12) Patent Application Publication
(10) Pub. No.: US 2026/0129881 A1
(43) Pub. Date: May 7, 2026

(54) THIN FILM RESISTOR AND THIN FILM METAL-INSULATOR-METAL CAPACITOR IN INTEGRATED CIRCUIT

(71) Applicant: Microchip Technology Incorporated, Chandler, AZ (US)

(72) Inventors: Paul Fest, Chandler, AZ (US); Brandon Lent, Gilbert, AZ (US); Jeff Peters, Gilbert, AZ (US); Kevin Clark, Chandler, AZ (US)

(73) Assignee: Microchip Technology Incorporated, Chandler, AZ (US)

(21) Appl. No.: 19/185,860

(22) Filed: Apr. 22, 2025

Related U.S. Application Data
(60) Provisional application No. 63/716,899, filed on Nov. 6, 2024.

(51) Int. Cl. H10D 1/47; H01L 21/3205; H01L 23/522; H10D 1/00; H10D 1/68

(52) U.S. Cl. CPC H10D 1/474; H10D 1/021; H10D 1/041; H10D 1/692; H10P 14/414; H10W 20/495; H10W 20/498

(57) ABSTRACT

A method is provided for forming a thin film resistor (TFR) and a thin film MIM capacitor (TFMIMCAP) in an integrated circuit (IC) device. A method comprises: forming a thin film layer over an integrated circuit (IC) structure; annealing the thin film layer; and forming first and second thin film elements in the thin film layer. An integrated circuit device comprises: an integrated circuit (IC) structure; an annealed thin film layer above the IC structure; and first and second thin film elements in the thin film layer.

### RELATED PATENT APPLICATION

This application claims priority to commonly owned United States Provisional Patent Application No. 63/716,899 filed Nov. 6, 2024, the entire contents of which are hereby incorporated by reference for all purposes.

### TECHNICAL FIELD

The present disclosure relates to thin film resistors (TFRs) and thin film metal-insulator-metal capacitors (TFMIMCAPs) and methods for forming TFRs and TFMIMCAPs, in particular, TFRs and TFMIMCAPs in integrated circuits and methods for forming TFRs and TFMIMCAPs in integrated circuits.

### BACKGROUND

Semiconductor device technologies may integrate many different functions on a single chip. For example, analog and digital circuits may be produced on a single chip. Capacitors and resistors may be components in electrical circuits.

A thin film resistor (TFR) may include any suitable resistive film formed on or in an insulating substrate. Some common IC-integrated TFR resistive film materials include SiCr, SiCCr, TaN, and TiN. Thin film resistors (TFR), typically made of deposited homogenous metal thin film, offer technical advantages in terms of low temperature coefficient of resistance, smooth electron flow and long-term stability, which make them suitable for use in high precision radio frequency applications. Fabricating integrated TFRs typically employs the addition of numerous processing steps to the backend IC integration flow, such as several expensive photomask processes.

In semiconductor devices, it is desirable for capacitors to be small in size while having large capacitances. A MIM capacitor, such as a thin film metal-insulator-metal (TFMIMCAP) capacitor, may be capable of achieving a large capacitance while being small in size. Additionally, in semiconductor devices, it is desirable for capacitors to have a low voltage coefficient. The voltage coefficient is a measure of how much the capacitor varies with voltage. A MIM capacitor, such as a thin film metal-insulator-metal (TFMIMCAP) capacitor, may be capable of achieving a low voltage coefficient. A MIM capacitor is typically formed within the interconnect layers of an integrated circuit.

Semiconductor devices often have both capacitors and resistors integrated into a small area. Many integrated circuit (“IC”) devices incorporate thin film resistors (TFRs) or thin film MIM capacitors via fabrication of a Back-End-Of-Line (BEOL) structure. In conventional semiconductor fabrication processes, the MIM capacitor and the TFR are fabricated separately. The thin film suitable for forming the TFR is typically too resistive to be used as the MIM capacitor plate. Also, the thinness of the TFR usually imposes a particular patterning and etching process to form good electrical contact without damage to the thin resistor material. As such, adding a TFR to an integrated circuit including a MIM capacitor and vice-versa, typically results in significant additional cycle time and cost.

There is a need for low-cost methods for integrating thin film resistors (TFRs) and thin film metal-insulator-metal capacitors (TFMIMCAPs) in integrated circuits.

### SUMMARY OF THE INVENTION

According to an aspect, there is provided a method comprising: forming a thin film layer over an integrated circuit (IC) structure; annealing the thin film layer; and forming first and second thin film elements in the thin film layer.

An aspect provides a method as in the preceding paragraph, wherein the first thin film element comprises a thin film resistor (TFR), and wherein the second thin film element comprises a thin film metal-insulator-metal capacitor (TFMIMCAP).

An aspect provides a method as in one of the preceding two paragraphs, wherein forming first and second thin film elements comprises: forming a thin film hardmask layer over the thin film layer; forming and patterning a photomask over the thin film hardmask layer; performing a first etch process to remove selected portions of the thin film hardmask layer to define a thin film hardmask, wherein the first etch process stops at the thin film layer; removing the photomask; and performing a second etch process using the thin film hardmask as a hardmask to remove selected portions of the thin film layer to define the first thin film element and the second thin film element under the thin film hardmask.

An aspect provides a method as in one of the preceding three paragraphs, wherein the thin film hardmask layer comprises silicon nitride (SiN).

An aspect provides a method as in one of the preceding four paragraphs, wherein the second etch process rounds upper corners of the thin film hardmask.

An aspect provides a method as in one of the preceding five paragraphs, comprising forming a dielectric etch stop layer over the IC structure prior to forming the thin film layer, wherein the second etch process stops at the dielectric etch stop layer.

An aspect provides a method as in one of the preceding six paragraphs, comprising: forming an oxide insulator/capacitance layer; performing a third etch process to form a first oxide layer opening in the oxide insulator/capacitance layer over the first thin film element and a second oxide layer opening in the oxide insulator/capacitance layer over the second thin film element; performing a fourth etch process through the first and second oxide layer openings to form first and second thin film contact openings in the thin film hardmask over the first and second thin film elements, respectively, thereby exposing surfaces of the first and second thin film elements, respectively; forming a metal interconnect layer, over the IC structure, comprising: a first metal interconnect element coupled to at least one of the plurality of conductive IC element contacts, a second metal interconnect extending into the first thin film contact opening to contact the underlying first thin film element, and a third metal interconnect extending into the second thin film contact opening to contact the underlying second thin film element.

An aspect provides a method as in one of the preceding seven paragraphs, wherein the metal interconnect layer comprises aluminum (Al), aluminum silicon (AlSi), or aluminum silicon copper (AlSiCu).

An aspect provides a method as in one of the preceding eight paragraphs, wherein the IC structure includes a transistor including at least one conductive IC element contact connected to at least one of a source region, a drain region, and a gate region of the transistor.

An aspect provides a method as in one of the preceding nine paragraphs, wherein the thin film layer comprises silicon carbon chromium (SiCCr), silicon chromium (SiCr), chromium silicon nitride (CrSiN), tantalum nitride (TaN), tantalum silicide (Ta₂Si), or titanium nitride (TiN).

An aspect provides a method as in one of the preceding ten paragraphs, wherein annealing comprises heating the thin film layer at a temperature of at least 500° C. for at least 20 minutes.

An aspect provides a method as in one of the preceding eleven paragraphs, comprising annealing the thin film layer at a time after forming the thin film layer and before forming the metal interconnect layer.

According to an aspect, there is provided an integrated circuit device comprising: an integrated circuit (IC) structure; an annealed thin film layer above the IC structure; and first and second thin film elements in the thin film layer.

An aspect provides an integrated circuit device as in the preceding paragraph, wherein the first thin film element is a thin film resistor, and wherein the second thin film element is a thin film metal-insulator-metal capacitor.

An aspect provides an integrated circuit device as in one of the preceding two paragraphs, comprising a metal interconnect layer, over the IC structure, comprising aluminum (Al), aluminum silicon (AlSi), or aluminum silicon copper (AlSiCu), and comprising: a first metal interconnect element coupled to a conductive IC element contact, a second metal interconnect coupled to the thin film resistor, and a third metal interconnect coupled to the thin film metal-insulator-metal capacitor.

An aspect provides an integrated circuit device as in one of the preceding three paragraphs, wherein the IC structure includes a transistor including at least one conductive IC element contact connected to at least one of a source region, a drain region, and a gate region of the transistor.

An aspect provides an integrated circuit device as in one of the preceding four paragraphs, wherein the thin film layer comprises silicon carbon chromium (SiCCr), silicon chromium (SiCr), chromium silicon nitride (CrSiN), tantalum nitride (TaN), tantalum silicide (Ta₂Si), or titanium nitride (TiN).

According to an aspect, there is provided an integrated circuit device comprising: an integrated circuit (IC) structure; an annealed thin film layer, above the IC structure, comprising silicon carbon chromium (SiCCr), silicon chromium (SiCr), chromium silicon nitride (CrSiN), tantalum nitride (TaN), tantalum silicide (Ta₂Si), or titanium nitride (TiN); a thin film hardmask layer, over the thin film layer, comprising silicon nitride (SiN); a thin film resistor in the thin film layer; and a thin film metal-insulator-metal capacitor in the thin film layer.

An aspect provides an integrated circuit device as in the preceding paragraph, comprising a metal interconnect layer, over the IC structure, comprising aluminum (Al), aluminum silicon (AlSi), or aluminum silicon copper (AlSiCu), and comprising: a first metal interconnect element coupled to a conductive IC element contact, a second metal interconnect coupled to the thin film resistor, and a third metal interconnect coupled to the thin film metal-insulator-metal capacitor.

An aspect provides an integrated circuit device as in one of the preceding two paragraphs, wherein the IC structure includes a transistor including at least one conductive IC element contact connected to at least one of a source region, a drain region, and a gate region of the transistor.

### BRIEF DESCRIPTION OF THE DRAWINGS

The figures illustrate examples of methods for forming TFRs and TFMIMCAPs in integrated circuits and illustrate integrated circuit devices with TFRs and TFMIMCAPs.

FIG. 1A represents a state during an IC fabrication process after formation of tungsten contacts and a chemical mechanical polish (W CMP) process at the top of the structure, which may represent conventional front-end processing up to W CMP.

FIG. 1B illustrates the example integrated circuit (IC) structure as shown in FIG. 1A, wherein a thin film layer stack is formed over the bulk insulation region and conductive contacts.

FIG. 1C illustrates the example integrated circuit (IC) structure as shown in FIG. 1B, wherein first photomasks may be formed and patterned on the thin film etch stop layer for forming a thin film, in this example at locations laterally offset from the underlying transistor structure.

FIG. 1D illustrates the example integrated circuit (IC) structure as shown in FIG. 1C, wherein remaining portions of the first photomasks may be stripped to reveal the etch stop layer.

FIG. 1E illustrates the example integrated circuit (IC) structure as shown in FIG. 1D, wherein a dry etch may then be performed to remove exposed portions of the thin film etch stop layer and underlying thin film layer.

FIG. 1F illustrates the example integrated circuit (IC) structure as shown in FIG. 1E, wherein an oxide insulator/capacitance layer is formed over the structure.

FIG. 1G illustrates the example integrated circuit (IC) structure as shown in FIG. 1F, wherein second photomasks are formed on the oxide insulator/capacitance layer and patterned over selected areas of the thin film etch stop layer and thin film elements.

FIG. 1H illustrates the example integrated circuit (IC) structure as shown in FIG. 1G, wherein a first thin film contact etch is performed to (a) remove selected portions of the oxide insulator/capacitance layer to define oxide layers having oxide layer openings, respectively.

FIG. 1I illustrates the example integrated circuit (IC) structure as shown in FIG. 1H, wherein a second thin film contact etch may be performed to remove portions of the thin film etch stop layer and remove portions of the dielectric etch stop layer.

FIG. 1J illustrates the example integrated circuit (IC) structure as shown in FIG. 1I, wherein a first metal layer/interconnect layer is formed, referred to as a “Metal 1” layer.

FIG. 1K illustrates the example integrated circuit (IC) structure as shown in FIG. 1J, wherein a third photomask may be formed and patterned over the Metal 1 layer.

FIG. 1L illustrates the example integrated circuit (IC) structure as shown in FIG. 1K, wherein the Metal 1 layer may be etched using the third photomask to define a plurality of Metal 1 elements.

FIG. 1M illustrates the example integrated circuit (IC) structure as shown in FIG. 1L, wherein a fourth photomask is applied to the inter-metal dielectric (IMD) layer.

FIG. 1N illustrates the example integrated circuit (IC) structure as shown in FIG. 1M, wherein a plurality of conductive contacts are formed in the inter-metal dielectric (IMD) layer and a Metal 2 layer is deposited and patterned on the inter-metal dielectric (IMD) layer to connect the aluminum interconnect element (now the top plate of thin film MIMCAP) with the Metal 2 layer by the plurality of conductive contacts.

FIG. 2 shows a flow chart of a method for integrating a thin film resistor (TFR) and a thin film metal-insulator-metal capacitor (TFMIMCAP) in a semiconductor integrated circuit (IC) device.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided techniques for integrating a thin film resistor (TFR) and a thin film metal-insulator-metal capacitor (TFMIMCAP) in a semiconductor integrated circuit (IC) device, which may provide a cost reduction as compared with conventional techniques. In some embodiments, the TFR and TFMIMCAP are formed after IC elements and IC element contacts (e.g. tungsten contacts) are formed, but before the first metal/interconnect layer (“Metal 1” layer) is formed. This may allow a TFR and TFMIMCAP anneal to be performed (e.g., to adjust the value of the thin film), for example at a temperature of 500° C. or above (e.g., in the range of 500°-525° C.). Thus, annealed TFRs and TFMIMCAPs may be integrated into IC devices that use aluminum interconnects (aluminum (Al), aluminum silicon (AlSi), or aluminum silicon copper (AlSiCu)), because the aluminum interconnects (which are generally not tolerant of the high temperatures experienced during a typical TFR anneal) are not formed until after the thin film anneal. The thin film anneal may be performed at any time in the process prior to depositing the first metal/interconnect layer.

Aspects of the process of forming the integrated TFR and TFMIMCAP adds two additional photomasks to the baseline IC production flow. In some aspects, the TFR and TFMIMCAP formation process includes forming a thin film etch stop layer (e.g., a SiN layer) over the IC structure (and under the thin film elements), which protects underlying IC elements (e.g., memory elements and tungsten contacts) to thereby allow chemical cleans to be performed to remove polymer residue formed during at least one etch process. In addition, a second thin film etch stop layer (e.g., SiN layer) may be formed over the thin film elements, which may act as an etch stop during a thin film contact etch for forming contact openings for coupling a metal interconnect layer (e.g., Metal 1 layer) to the thin film elements.

In other aspects, a nitride layer (e.g., SiN layer) and/or an oxide layer formed over the thin film layer collectively act as a hardmask during a thin film etch for defining thin film elements from a thin film layer. Providing such a hardmask may remove a process step that uses a photomask for the thin film etch, to thereby eliminate or greatly reduce the formation of polymer material during the thin film etch process, thus eliminating or reducing chemical cleans to remove such polymer material. In addition, the oxide insulator/capacitance layer may become rounded during the thin film etch, which may help prevent the occurrence of electrical shorts (“stringers”) along the thin film elements and between adjacent metal layer structures (e.g., Metal 1 layer structures).

One aspect provides a method for forming both a thin film resistor (TFR) and a thin film metal-insulator-metal capacitor (TFMIMCAP) using the same process steps and process order. Aspects may allow for the realization of two precision devices for the manufacturing cost of one.

According to one aspect, there is provided a thin film layer used as the bottom plate of the TFMIMCAP and an aluminum alloy layer used as the top plate. The aluminum alloy layer may comprise aluminum (Al), aluminum silicon (AlSi), or aluminum silicon copper (AlSiCu). This integration may use two masks to execute. This integration may be used with any process that uses an aluminum interconnect.

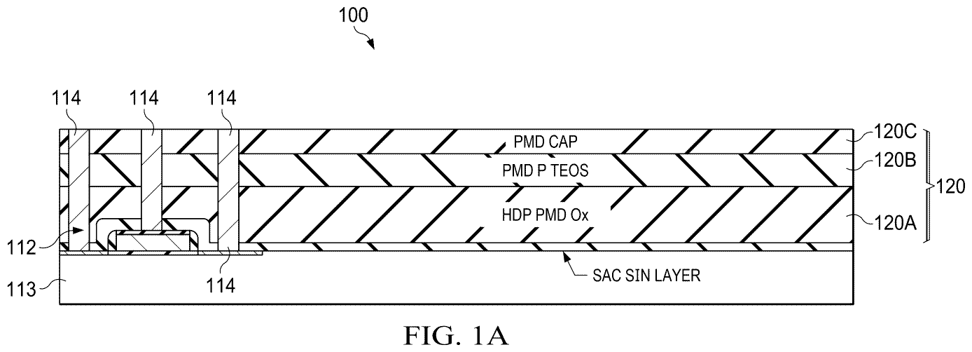

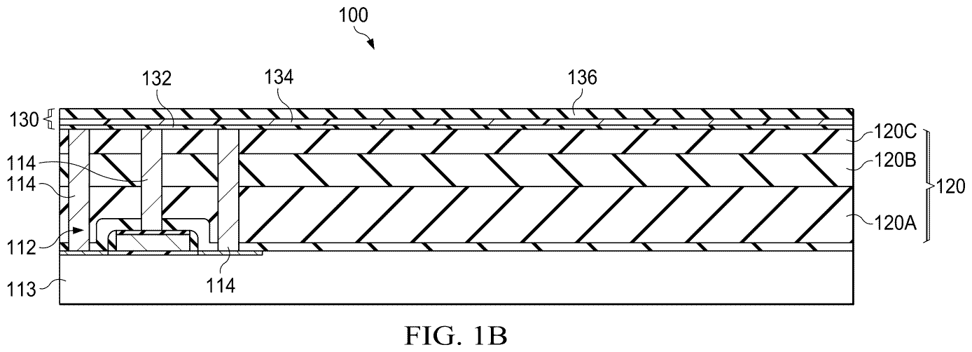

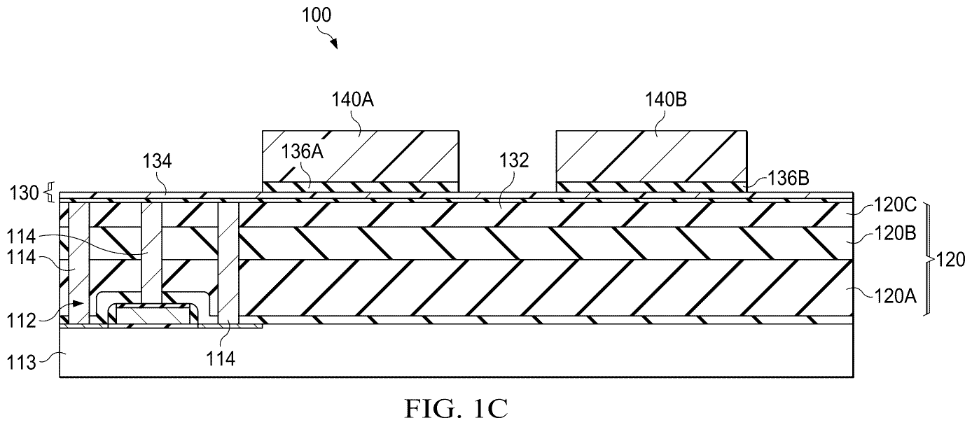

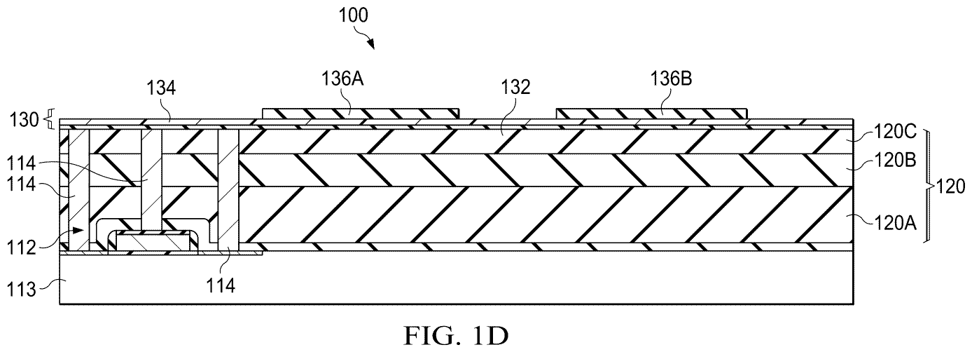

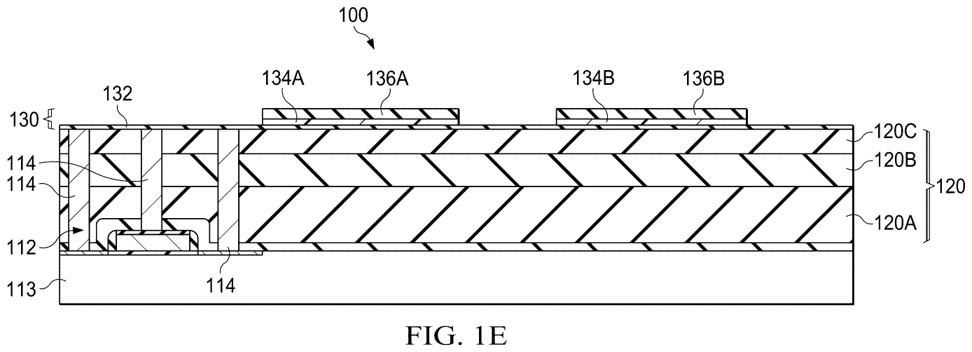

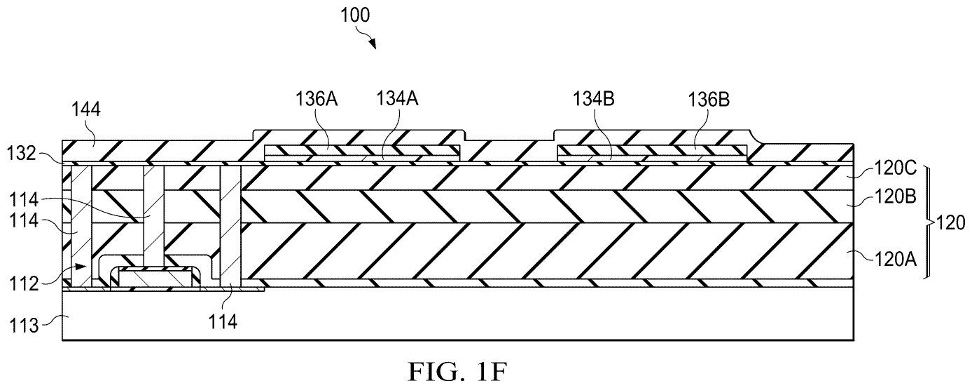

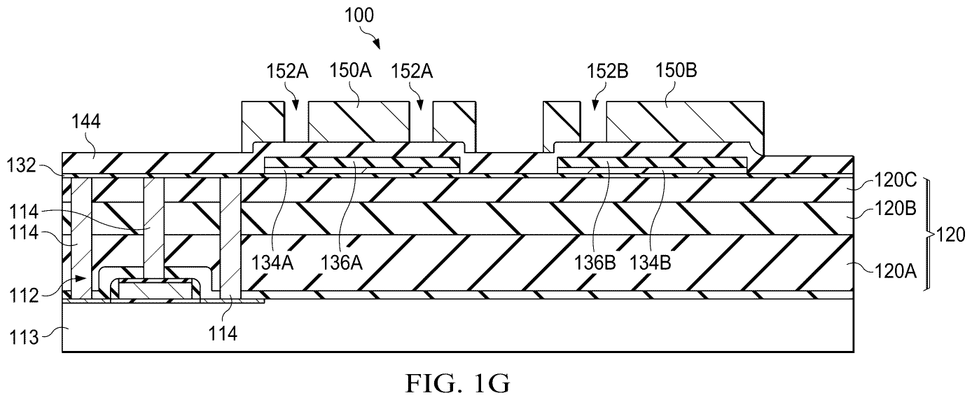

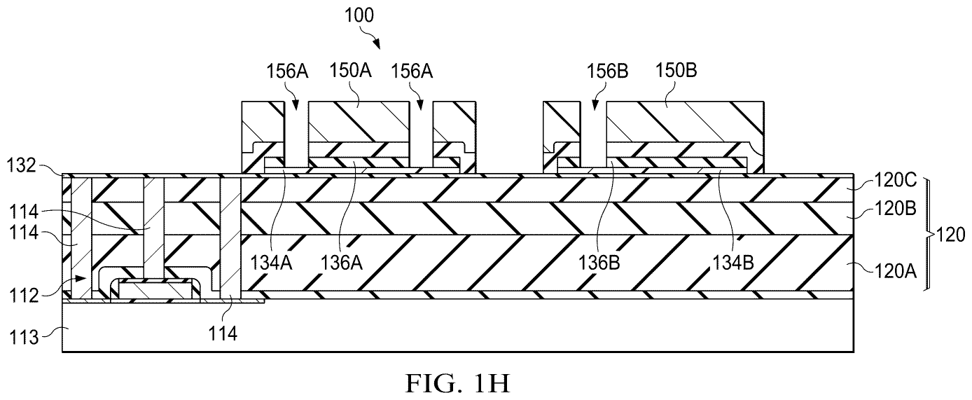

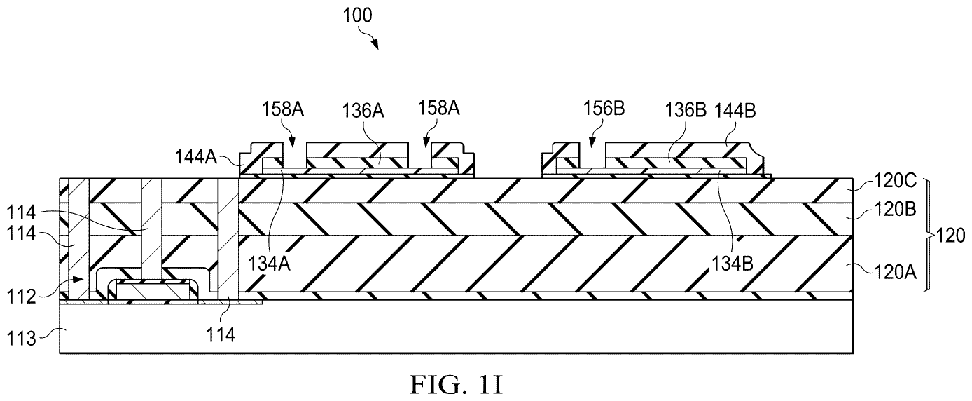

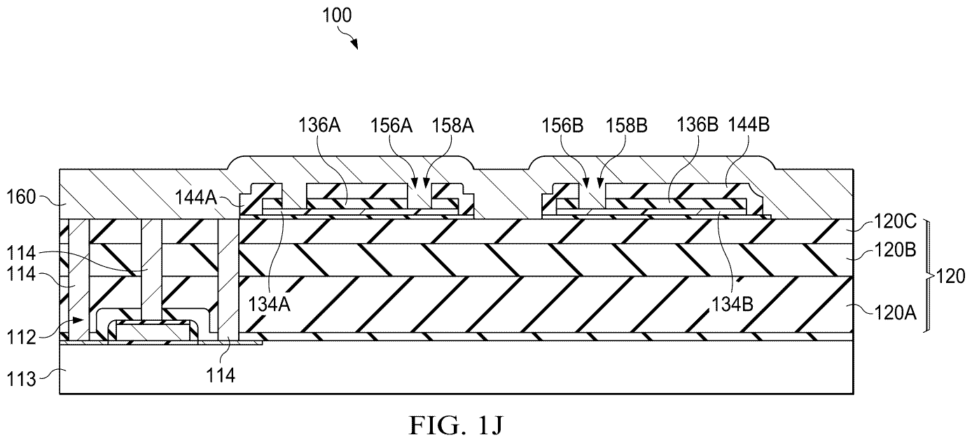

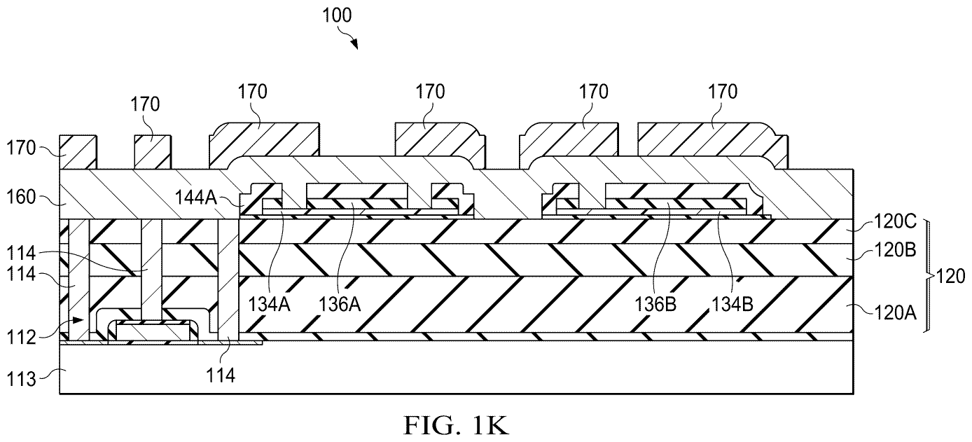

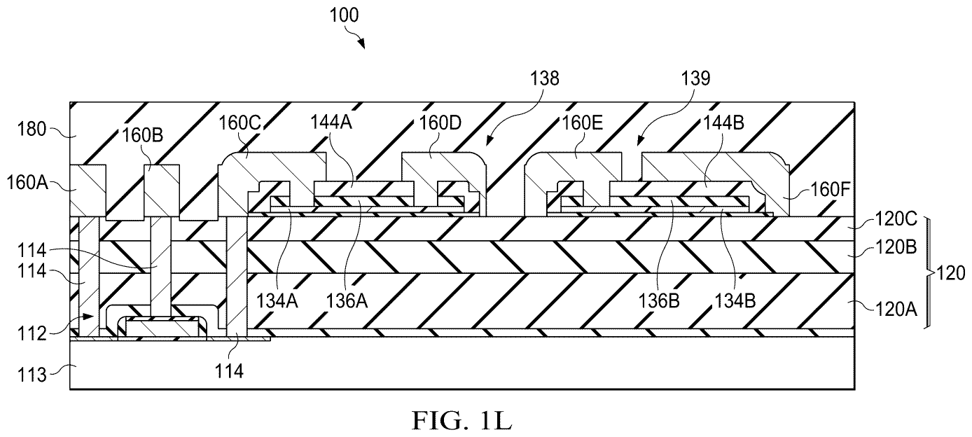

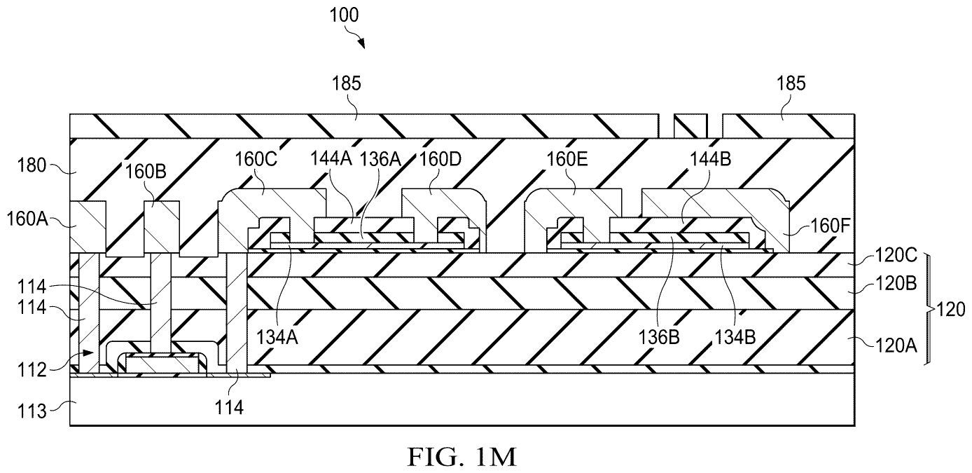

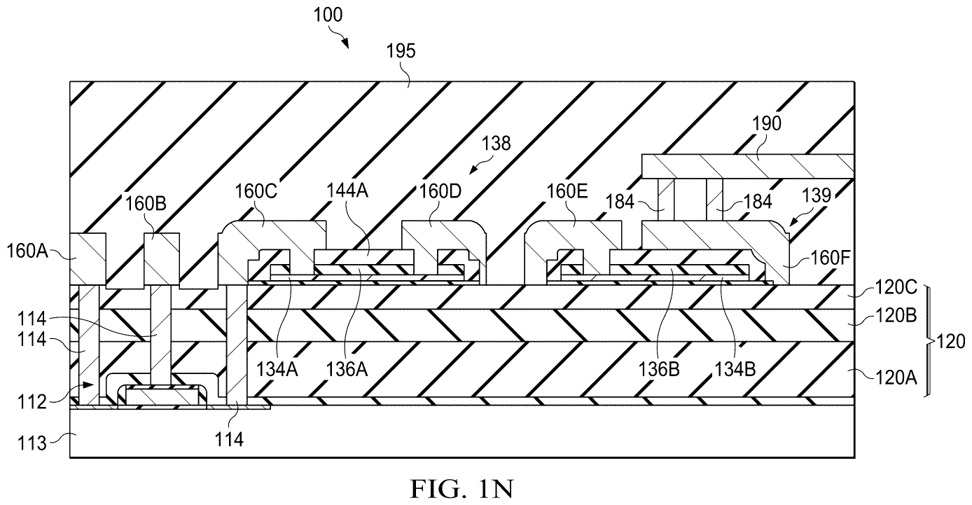

FIGS. 1A-1N illustrate a method of integrating a thin film resistor (TFR) and thin film metal-insulator-metal capacitor (TFMIMCAP) in a semiconductor integrated circuit (IC) device, according to a first example aspect. FIGS. 1A-1N further illustrate and integrated circuit device having a thin film resistor (TFR) and a thin film metal-insulator-metal capacitor (TFMIMCAP).

FIG. 1A illustrates an example integrated circuit (IC) structure 100, e.g., during the manufacturing of an IC device. In this example, the IC structure 100 includes a transistor structure 112 formed over a substrate 113, with a plurality of conductive contacts 114, e.g., tungsten contacts, extending though a bulk insulation region 120 formed over the transistor structure 112. However, the IC structure 100 may include any other IC devices(s) or structure(s), e.g., one or more full or partial memory cells or memory cell structures, and conductive contacts associated with such structures. In this example, the bulk insulation region 120 includes (a) a high-density plasma (HDP) pre-metal dielectric (PMD) oxide layer 120A, (b) a PMD oxide film 120B, e.g., PMD P TEOS (phosphorous-doped tetraethyl orthosilicate film), and (c) a PMD layer 120C.

FIG. 1A may represent a state during an IC fabrication process after formation of tungsten contacts 114 and a chemical mechanical polish (W CMP) process at the top of the structure 100, which may represent conventional front-end processing up to W CMP.

FIG. 1B illustrates the example integrated circuit (IC) structure 100 as shown in FIG. 1A, wherein a thin film layer stack 130 is formed over the bulk insulation region 120 and conductive contacts 114. First, a dielectric etch stop layer 132, e.g., a SiN layer, may be formed, e.g., to protect the tungsten contacts 114 from a subsequent thin film etch shown below at FIG. 1D. A thin film layer 134 may then be formed on the dielectric etch stop layer 132. The thin film layer 134 may comprise, SiCCr, SiCr, TaN, TiN, or any other suitable thin film material.

In some embodiments, e.g., the example embodiment shown in FIGS. 1A-1M, a thin film anneal may be performed at this point, e.g., to tune or adjust a temperature coefficient of resistance (TCR) of the thin film layer 134. For example, an anneal may be performed at a temperature of ≥500° C. In some embodiments, the thin film anneal may comprise an anneal at 515° C.±10° C. for a duration of 15-60 minutes, e.g., 30 minutes. In other embodiments, the thin film anneal may be performed at any other point in the process, prior to the deposition of the first metal layer/interconnect layer 160 (e.g., “Metal 1” layer) discussed below with reference to FIG. 1K. For example, in some embodiments, the thin film anneal may be performed after forming the thin film etch stop layer 136 discussed below. In other embodiments, the thin film anneal may be performed after etching to define the thin film element 134A discussed below with respect to FIG. 1D. In other embodiments, the thin film anneal may be performed after completing the thin film contact etch described below with respect to FIG. 1J.

After the thin film anneal shown in FIG. 1B, a thin film etch stop layer 136 may be formed on the thin film layer 134. In this embodiment, the thin film etch stop layer 136 comprises a SiN layer.

FIG. 1C illustrates the example integrated circuit (IC) structure 100 as shown in FIG. 1B, wherein first photomasks 140A and 140B may be formed and patterned on the thin film etch stop layer 136 (e.g., using known photolithographic techniques) for forming a thin film, in this example at locations laterally offset from the underlying transistor structure 112. The thin film etch stop layer 136 is etched to remove the exposed portions and to define etch stop layer 136A and etch stop layer 136B.

FIG. 1D illustrates the example integrated circuit (IC) structure 100 as shown in FIG. 1C, wherein the first photomasks 140A and 140B are stripped after the film etch stop layer 136 is etched. The dry etch may etch stop layer 136 (stopping on thin film layer 134). The first photomasks 140A and 140B are then removed. This may avoid polymer generation during the etch of thin film layer 134. The etch stop layer 136A and etch stop layer 136B are now configured to serve as photomasks for an etch process of the thin film layer 134. In some embodiments, a chemical clean may be used to strip the remaining portions of the first photomasks 140A and 140B, because the underlying tungsten contacts 114 are protected by the thin film element 134.

FIG. 1E illustrates the example integrated circuit (IC) structure 100 as shown in FIG. 1D, a dry etch may then be performed to remove exposed portions of the thin film layer 134 to define thin film element 134A and thin film element 134B. As shown, the etch may be configured to stop at the dielectric etch stop layer 132, which may protect the underlying structure, including the tungsten contacts 114.

FIG. 1F illustrates the example integrated circuit (IC) structure 100 as shown in FIG. 1E, wherein an oxide insulator/capacitance layer 144 is formed over the structure. In some embodiments, the oxide insulator/capacitance layer 144 may comprise the same material as the PMD layer 120C below the dielectric etch stop layer 132, but may have a reduced thickness as compared with the PMD layer 120C. A portion of the oxide insulator/capacitance layer 144 may become an TFMIMCAP dielectric and set the capacitance and breakdown voltage of the TFMIMCAP.

FIG. 1G illustrates the example integrated circuit (IC) structure 100 as shown in FIG. 1F, wherein second photomasks 150A and 150B are formed on the oxide insulator/capacitance layer 144 and patterned over selected areas of the thin film etch stop layer 136A and 136B and thin film elements 134A and 134B to define mask openings 152A and 152B respectively aligned over the thin film elements 134A and 134B. This patterns both the thin film resistor contacts and thin film MIMCAP bottom plate contact in layer 144, but may stop on thin film etch stop layers 136A and 136B as shown in FIG. 1H.

FIG. 1H illustrates the example integrated circuit (IC) structure 100 as shown in FIG. 1G, wherein a first thin film contact etch is performed to (a) remove selected portions of the oxide insulator/capacitance layer 144 to define oxide layers 144A and 144B having oxide layer openings 156A and 156B, respectively. The first thin film contact etch may stop on the dielectric etch stop layer 132 at areas outside the outer perimeter of second photomasks 150A and 150B, and may stop on the etch stop layer 136A and 136B at the bottoms of the oxide layer openings 156A and 156B within the outer perimeter of the second photomasks 150A and 150B.

The first thin film contact etch may be a wet etch or a dry etch. A wet etch may improve the flow of metal during a subsequent metal deposition (e.g., the Metal 1 layer deposition shown in FIG. 1K), and may reduce the occurrence of electrical shorts (often referred to as “stringers”) along the thin film elements 134A and 134B and between adjacent metal structures (e.g., Metal 1 layer structures).

FIG. 1I illustrates the example integrated circuit (IC) structure 100 as shown in FIG. 1H, wherein a second thin film contact etch may be performed to (a) remove portions of the thin film etch stop layer 136A and 136B exposed through the oxide layer openings 156A and 156B in the oxide layers 144A and 144B to define thin film contact openings 158A and 158B that expose a top surface of the thin film element 134A and a top surface of the thin film element 134B and (b) remove portions of the dielectric etch stop layer 132 exposed outside the perimeter of the oxide layers 144A and 144B which may expose a top surface of the PMD layer 120C and the underlying tungsten contacts 114. In an embodiment in which dielectric etch stop layer 132 comprises a SiN layer, the second thin film contact etch may comprise a gentle SiN clear etch with high selectivity to oxide, to protect the underlying tungsten contacts 114. This allows the next metal layer to contact the thin film resistor and the thin film MIMCAP, or other underlying conductors, wherein the thin film layer 134A will become the thin film resistor and the thin film layer 134B will become the thin film MIMCAP bottom plate. The remaining portions of the second photomasks 150A and 150B (see FIG. 1H) may be removed, e.g., by a resist strip. In some embodiments, a chemical clean may be used to remove remaining portions of the second photomasks 150A and 150B because underlying IC structures, e.g., the tungsten contacts 114, are protected by the dielectric etch stop layer 132.

FIG. 1J illustrates the example integrated circuit (IC) structure 100 as shown in FIG. 1I, wherein the IC device processing may continue, by forming a first metal layer/interconnect layer, referred to as a “Metal 1” layer 160. In the illustrated embodiment, Metal 1 layer 160 comprises aluminum. In other embodiments, Metal 1 layer 160 may comprise copper or other metal. As shown, Metal 1 layer 160 extends into the oxide layer openings 156A and thin film contact openings 158A, to thereby contact the thin film element 134A at disparate contact locations of the thin film element 134A, e.g., at contact locations at or near opposing lateral sides or ends of the thin film element 134A. As shown, Metal 1 layer 160 also extends into the oxide layer opening 156B and thin film contact opening 158B, to thereby contact the thin film element 134B at the contact location of the thin film element 134B, e.g., at a contact location at or near a side or end of the thin film element 134B. Metal 1 layer 160 also extends over, and is in contact with, tungsten contacts 114.

FIG. 1K illustrates the example integrated circuit (IC) structure 100 as shown in FIG. 1J, wherein a third photomask 170 may be formed and patterned over the Metal 1 layer 160.

FIG. 1L illustrates the example integrated circuit (IC) structure 100 as shown in FIG. 1K, wherein the aluminum Metal 1 layer 160 may be etched using the third photomask 170 to define a plurality of aluminum Metal 1 elements (e.g., metal interconnect elements) 160A-160F, and the remaining photomask material 170 of FIG. 1L may then be removed. For example, as shown, the Metal 1 layer 160 may be etched to define aluminum interconnect elements 160A and 160B in contact with tungsten contacts 114, and aluminum interconnect elements 160C and 160D in contact with the disparate contact locations of the thin film element 134A, which is now a thin film resistor. In this example illustration, a first aluminum interconnect element 160C conductively connects a first contact location of the thin film element 134A (now thin film resistor) with a tungsten via 114A coupled to a source or drain region of the transistor 112, and a second interconnect element 160D conductively contacts a second contact location of the thin film element 134A (now thin film resistor) with other IC element structure(s) (not shown). The thin film element 134A and the first and second interconnect elements 160C and 160D collectively define an integrated thin film resistor, indicated at 138.

As shown in FIG. 1L, when the Metal 1 layer 160 is etched aluminum interconnect elements 160E and 160F are defined. The interconnect element 160E is in contact with the thin film element 134B (now the bottom plate of thin film MIMCAP). The aluminum interconnect element 160F (now the top plate of thin film MIMCAP) is also defined. The thin film element 134A (now the bottom plate of thin film MIMCAP), the interconnect element 160E, and the interconnect element 160F (now the top plate of thin film MIMCAP) collectively define an integrated thin film metal-insulator-metal capacitor, indicated at 139. An inter-metal dielectric (IMD) layer 180 is then added to the integrated circuit (IC) structure 100.

FIG. 1M illustrates the example integrated circuit (IC) structure 100 as shown in FIG. 1L, wherein a fourth photomask 185 is applied to the inter-metal dielectric (IMD) layer 180. The fourth photomask 185 is patterned to allow a plurality of conductive contacts to be created in the inter-metal dielectric (IMD) layer 180.

FIG. 1N illustrates the example integrated circuit (IC) structure 100 as shown in FIG. 1M, wherein a plurality of conductive contacts 184, e.g., tungsten contacts, are formed in the inter-metal dielectric (IMD) layer. A Metal 2 layer 190 is deposited on the inter-metal dielectric (IMD) layer to connect the aluminum interconnect element 160F (now the top plate of thin film MIMCAP) with the Metal 2 layer 190 by the plurality of conductive contacts 184, e.g., tungsten contacts. Additional inter-metal dielectric (IMD) layer 195 is deposited to encapsulate the integrated circuit (IC) structure 100, including the integrated thin film resistor 138 and the integrated thin film metal-insulator-metal capacitor 139.

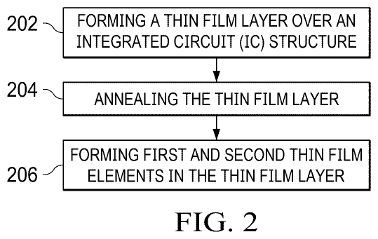

FIG. 2 shows a flow chart of a method for integrating a thin film resistor (TFR) and a thin film metal-insulator-metal capacitor (TFMIMCAP) in a semiconductor integrated circuit (IC) device. A thin film layer is formed 202 over an integrated circuit (IC) structure. The thin film layer is annealed 204. First and second thin film elements are formed 206 in the thin film layer.

Although examples have been described above, other variations and examples may be made from this disclosure without departing from the spirit and scope of these disclosed examples.

1. A method comprising:
forming a thin film layer over an integrated circuit (IC) structure;
annealing the thin film layer; and
forming first and second thin film elements in the thin film layer.

2. The method of claim 1, wherein the first thin film element comprises a thin film resistor (TFR), and wherein the second thin film element comprises a thin film metal-insulator-metal capacitor (TFMIMCAP).

3. The method of claim 1, wherein forming first and second thin film elements comprises:
forming a thin film hardmask layer over the thin film layer;
forming and patterning a photomask over the thin film hardmask layer;
performing a first etch process to remove selected portions of the thin film hardmask layer to define a thin film hardmask, wherein the first etch process stops at the thin film layer;
removing the photomask; and
performing a second etch process using the thin film hardmask as a hardmask to remove selected portions of the thin film layer to define the first thin film element and the second thin film element under the thin film hardmask.

4. The method of claim 3, wherein the thin film hardmask layer comprises silicon nitride (SiN).

5. The method of claim 3, wherein the second etch process rounds upper corners of the thin film hardmask.

6. The method of claim 3, comprising forming a dielectric etch stop layer over the IC structure prior to forming the thin film layer, wherein the second etch process stops at the dielectric etch stop layer.

7. The method of claim 3, comprising:
forming an oxide insulator/capacitance layer;
performing a third etch process to form a first oxide layer opening in the oxide layer over the first thin film element and a second oxide layer opening in the oxide insulator/capacitance layer over the second thin film element;
performing a fourth etch process through the first and second oxide layer openings to form first and second thin film contact openings in the thin film hardmask over the first and second thin film elements, respectively, thereby exposing surfaces of the first and second thin film elements, respectively; and
forming a metal interconnect layer, over the IC structure, comprising:
a first metal interconnect element coupled to at least one of the plurality of conductive IC element contacts,
a second metal interconnect extending into the first thin film contact opening to contact the underlying first thin film element, and
a third metal interconnect extending into the second thin film contact opening to contact the underlying second thin film element.

8. The method of claim 7, wherein the metal interconnect layer comprises aluminum (Al), aluminum silicon (AlSi), or aluminum silicon copper (AlSiCu).

9. The method of claim 1, wherein the IC structure includes a transistor including at least one conductive IC element contact connected to at least one of a source region, a drain region, and a gate region of the transistor.

10. The method of claim 1, wherein the thin film layer comprises silicon carbon chromium (SiCCr), silicon chromium (SiCr), chromium silicon nitride (CrSiN), tantalum nitride (TaN), tantalum silicide (Ta₂Si), or titanium nitride (TiN).

11. The method of claim 1, wherein annealing comprises heating the thin film layer at a temperature of at least 500° C. for at least 20 minutes.

12. The method of claim 7, comprising annealing the thin film layer at a time after forming the thin film layer and before forming the metal interconnect layer.

13. An integrated circuit device comprising:
an integrated circuit (IC) structure;
an annealed thin film layer above the IC structure; and
first and second thin film elements in the thin film layer.

14. The integrated circuit device of claim 13, wherein the first thin film element is a thin film resistor, and wherein the second thin film element is a thin film metal-insulator-metal capacitor.

15. The integrated circuit device of claim 14, comprising a metal interconnect layer, over the IC structure, comprising aluminum (Al), aluminum silicon (AlSi), or aluminum silicon copper (AlSiCu), and comprising:
a first metal interconnect element coupled to a conductive IC element contact,
a second metal interconnect coupled to the thin film resistor, and
a third metal interconnect coupled to the thin film metal-insulator-metal capacitor.

16. The integrated circuit device of claim 13, wherein the IC structure includes a transistor including at least one conductive IC element contact connected to at least one of a source region, a drain region, and a gate region of the transistor.

17. The integrated circuit device of claim 13, wherein the thin film layer comprises silicon carbon chromium (SiCCr), silicon chromium (SiCr), chromium silicon nitride (CrSiN), tantalum nitride (TaN), tantalum silicide (Ta₂Si), or titanium nitride (TiN).

18. An integrated circuit device comprising:
an integrated circuit (IC) structure;
an annealed thin film layer, above the IC structure, comprising silicon carbon chromium (SiCCr), silicon chromium (SiCr), chromium silicon nitride (CrSiN), tantalum nitride (TaN), tantalum silicide (Ta₂Si), or titanium nitride (TiN);
a thin film hardmask layer, over the thin film layer, comprising silicon nitride (SiN);
a thin film resistor in the thin film layer; and
a thin film metal-insulator-metal capacitor in the thin film layer.

19. The integrated circuit device of claim 18, comprising a metal interconnect layer, over the IC structure, comprising aluminum (Al), aluminum silicon (AlSi), or aluminum silicon copper (AlSiCu), and comprising:
a first metal interconnect element coupled to a conductive IC element contact,
a second metal interconnect coupled to the thin film resistor, and
a third metal interconnect coupled to the thin film metal-insulator-metal capacitor.

20. The integrated circuit device of claim 18, wherein the IC structure includes a transistor including at least one conductive IC element contact connected to at least one of a source region, a drain region, and a gate region of the transistor.
